(19) United States
(12) Patent Application Publication
(10) Pub. No.: US 2014/0174498 A1
(43) Pub. Date: Jun. 26, 2014

(54) SOLAR ENERGY PRODUCTION SYSTEM

(71) Applicant: CHROMx, LLC., Rancho Santa Margarita, CA (US)

(72) Inventor: Theodore Denis Fay, JR., Mission Viejo, CA (US)

(73) Assignee: CHROMx, LLC., Rancho Santa Margarita, CA (US)

(21) Appl. No.: 13/935,750

(22) Filed: Jul. 5, 2013

Related U.S. Application Data
(63) Continuation of application No. 12/048,926, filed on Mar. 14, 2008, now abandoned.

(51) Int. Cl. H01L 31/052

(52) U.S. Cl. CPC H01L 31/0524
USPC 136/246

(57) ABSTRACT

A device for generating solar electrical energy generally includes an optic for focusing solar radiation, a collimating optic, a semi-conductor optical gates wedge disposed near the focal point of the collimation optic for dispersing incident solar radiation between a plurality of adjacent wavelength bands, an array of photovoltaic cells, each cell being formed from a material for absorbing and converting a corresponding wavelength band dispersed by the wedge into the photovoltaic energy, and a refracting optic disposed between the wedge and the array for directing separated wavelength bands onto corresponding photovoltaic cells.

### CROSS-REFERENCE TO RELATED APPLICATIONS

This application is a continuation of U.S. patent application Ser. No. 12/048,926, filed Mar. 14, 2008, which is incorporated by reference herein in its entirety.

### BACKGROUND OF THE INVENTION

Solar photovoltaic (PV) cells currently furnish power for remote sites on earth and for space vehicles, where other power sources are expensive or unavailable. Solar PV technologies cannot yet compete for most central site power generation applications, because they are all significantly more expensive than other available energy sources (e.g. coal, gas, and nuclear).

Yet solar PV technology remains of interest because the existing forms of power generation are certainly going to become more costly as their supplies diminish. All forms of solar power are also renewable and eco-friendly. There is currently a push to make solar PV cells less costly and also to increase their efficiency (to convert solar energy directly into electricity).

The current global cost of electrical energy generation alone is roughly $300M/hr; and the overall “energy marketplace” is double that figure. Any energy production capability that can be installed at a lower cost than the current installation cost for coal fired or nuclear power will be warmly welcomed.

Current problems with solar PV cells are twofold. First, they cannot compete with traditional energy sources for central site power generation on the basis of their installed cost (roughly $7-$10/installed watt for solar versus $4-$5/watt for coal, nuclear, or natural gas). Second, solar PV cells currently require the same scarce semiconductor materials that are used in several numerous electronic industries (computers, LED, and diode laser). In order to make solar PV cells competitive as a source for electrical power generation, they must have much lower production costs, become significantly more efficient in their conversion of solar energy to electricity, and they must be made almost entirely of materials that are cheap and plentiful.

Current solar cell technology employs single junction cells for rooftop applications. Such cells typically are about 12% to 18% efficient and require purified silicon—which is in high demand by the electronics industry for other applications. In order to increase solar cell efficiency, numerous attempts have been made to build “multi-junction” cells. These stacked cells are designed such that the different layers of the cell absorb different energy bands of the incident solar energy.

Such multi-junction cells have been demonstrated to be more efficient—the best examples achieving efficiencies just in excess of 40% in the laboratory. However, the complexity restricts the materials (such as Ge, III-V) that must be used in their assembly and they are currently much more expensive than the single junction cells.

In the current manufacture of concentrating solar cells, maximum efficiencies of 40% or more can be achieved (Spectrolab, Boeing), but only if the thickness of each cell layer, including coatings, can be vapor deposited with great precision. The thickness of each cell layer must be precisely controlled to maintain the same electrical current production in every part of the cell. This is especially true for multi-junction cells, where equal currents between junctions require expensive, precision tunnel diodes between each junction. In addition to higher processing costs associated with precision manufacturing, these multi junction components must also be “lattice matched” with each other.

This means the cell designer is restricted to scarce, expensive, semiconductor alloy combinations in order to achieve precisely the same molecular lattice spacing at each junction.

To compete in the central site power generation marketplace, solar PV cells and concentrating systems must cost less than $2/installed Watt. Also, they must attain high efficiencies in order to make them “duty cycle” competitive. A typical central site power generation facility currently is “on station” for ˜20 hr/day. In the southwestern US, stationary, SOA solar panels produce electricity for only about 6 hours/day for a “duty cycle” of ˜25%. A solar cell that tracks the sun will produce electricity for an average of about 11 hours a day.

### SUMMARY OF THE INVENTION

A device in accordance with the present invention for generating solar photovoltaic energy generally includes an optic for focusing the solar radiation, followed by a collimating optic, a semiconductor optical gate wedge disposed for dispersing incident solar radiation into a plurality of adjacent wavelength bands. The wedge may include multiple coatings in order to reduce reflection losses.

An array of photovoltaic cells is provided with each cell formed from material for absorbing and converting a corresponding wavelength band, dispersed by the wedge, into electrical energy. A refracting optic is disposed between the wedge and the array for directing separated wavelength bands onto corresponding photovoltaic cells.

In this manner, each semi-conducting material in a cell in the dispersed array is disposed to only the wavelength range from the incident solar spectrum that matches the materials ability to absorb and convert sunlight into electricity.

These “unstacked” solar cell arrays can be built with much lower processing costs using plentiful and less expensive materials than existing multi-junction cells. The resulting photovoltaic (PV) cell array electrical/total power fraction (efficiency) will exceed 40% once each PV material and cell has been optimized for its appropriate photon wavelength or energy

In contrast, as hereinabove noted, the state of the art solar panel systems are restricted to an overall efficiency of 18% or less.

More particularly, a refracting optic is disposed between the wedge and the cell array for the purpose of directing separated wavelength bands onto corresponding photovoltaic cells. Each cell comprises a single junction, either III-V or Si, photovoltaic cell which significantly reduces the cost of the device.

More specifically, as an example, the array may include five cells with the first cell absorbing solar photons of energy between 0.95 and 1.15 eV, the second cell absorbing solar photons of energy between 1.2 and 1.4 eV, the third cell absorbing solar photons of energy between 1.45 and 1.7 eV, the fourth cell absorbing solar photons of energy between 1.75 and 2.1 eV, and the fifth cell absorbing solar photons of energy between 2.15 and 2.8 eV.

Still more particularly, the first cell may be formed from GaInAsP the second cell may be formed from Si, the third cell may be formed from GaAs, the fourth cell may be formed from GaInP and the fifth cell may be formed from Al₂GaInP₄.

To further increase the efficiency and effectiveness of the device, the refracting optic may be disposed for spatially dispersing light from the wedge onto the photovoltaic cells incident perpendicular to the cell surfaces.

A method in accordance with the present invention provides for optimization of a photovoltaic cell array, and generally includes focusing solar radiation onto a semi-conductor optical gate wedge, dispersing the solar radiation by way of the gate wedge into a plurality of adjacent wavelength bands, and directing the adjacent wavelengths bands such that they are incident perpendicular to the surfaces of the a photovoltaic cell array. More particularly, the method further includes arranging a plurality of single junction, either III-V or Si, photovoltaic cells which form a linear array.

### BRIEF DESCRIPTION OF THE DRAWINGS

The present invention may be more readily understood by consideration of the following detailed description when taken in conjunction with the accompanying drawings, in which:

FIG. 1 is a representation of the photovoltaic (PV) box in accordance with the present invention for generating solar photovoltaic energy which generally shows a collimation optic, a semi-conductor optical gate wedge, an array of photovoltaic cells, and an array optic disposed between the wedge and the array;

FIG. 2 is a representation of the solar energy production system, including a focusing optic disposed in an operative relationship with the PV box illustrated in FIG. 1;

FIG. 3 is a representation of one embodiment of the focusing optic shown in FIG. 2 in accordance with the present invention illustrating a Fresnel array with four mirrors;

FIG. 4 is a representative of an alternative embodiment of the focusing optic shown in FIG. 2 in accordance with the present invention illustrating a thirty-six mirror Fresnel array; and

FIG. 5 is a plot of electrical watts generated versus the solar spectrum as a function of photon energy in eV illustrating the efficiency of the device in accordance with the present invention through the use of an array of single junction diode photovoltaic cells.

### DETAILED DESCRIPTION

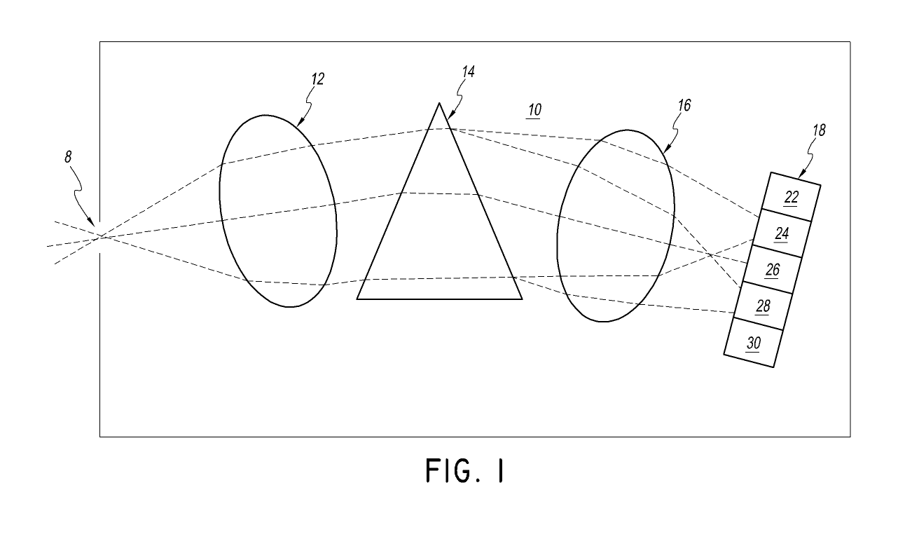

With reference to FIG. 1, there is represented a photovoltaic (PV) box 10 in accordance with the present invention for generating solar photovoltaic energy which generally includes a collimating optic 12, a semiconductor optical gate wedge 14 which may be coated if desired to selectively reflect incident radiation, a refracting optic 16 disposed between the wedge 14 and an array 18 of photovoltaic cells 22, 24, 26, 28, 30. The solar radiation enters the PV box 10 through the window opening 8.

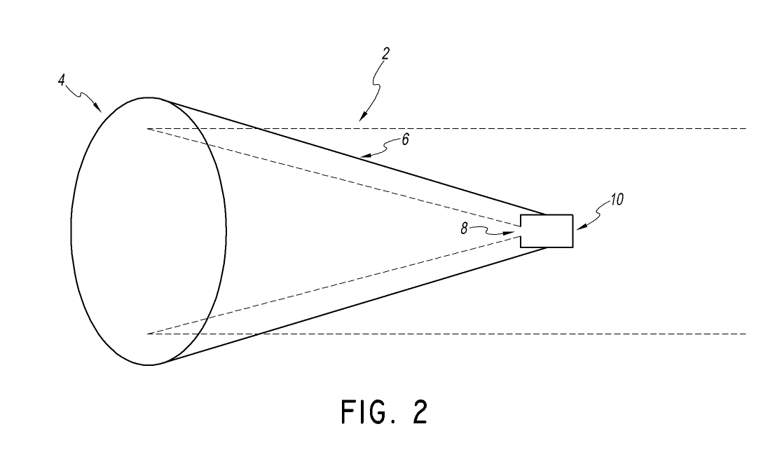

As represented in FIG. 2, the solar energy production system 2 consists of the focusing optic 4 which focuses solar radiation on the window opening 8 to the PV box 10. The PV box is attached to the support for the focusing optic 4 with several struts 6.

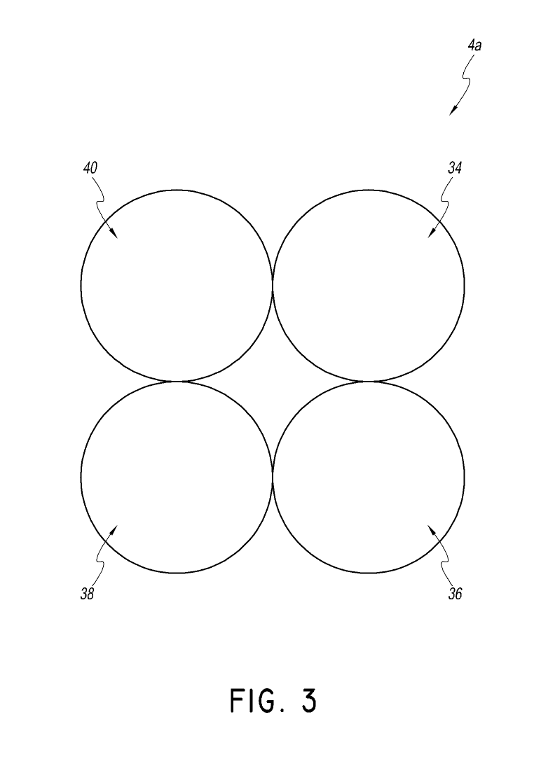

The focusing optic 4 may be of any suitable configuration and size as represented, for example, in FIG. 3 wherein focusing optic comprises a Fresnel array 4a of four mirrors 34, 36, 38, 40 each having a diameter of 0.5 m, which are spaced apart from two semiconductor optical gate wedges 14 at a distance of about 0.5 m. The wedges 14 have an area of about 0.04 m². Given solar input of 920 W/m² and a focusing optic collecting area of 0.78 m², the power at the wedges is about 722 W. With 40% efficiency, the power output would be almost 300 watts of electrical power. Suitable wedges 14 are described in U.S. Pat. Nos. 7,238,954 and 7,286,582 to Fay. These references are incorporated herewith in their entirety for the purpose of describing suitable wedges 14 for use in the present invention.

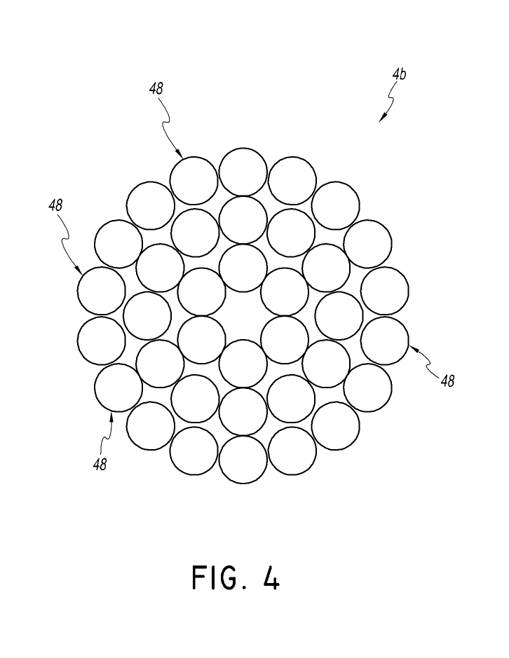

The PV box 10 may be scaled to any suitable size by increasing the size of the focusing optic 4, collimating optic 12, wedges 14, refracting optics 16, and the photovoltaic cell array 18. For example, as illustrated in FIG. 4, the focusing optic 4b may include an array of thirty-six mirrors arranged in three circles with a total diameter of 14 m and a collecting area of 113 m². Given solar input of 920 W/m² and a focusing optic collecting area of 113 m², the power at the wedges is about 105,000 W. With 40% efficiency, the power output would be almost 42,000 watts of electrical power. In this instance, nine wedges 14 may be utilized having an area of 0.18 m². The amount of solar energy collected utilizing the focusing optics 4a and 4b represent embodiments suitable for home and commercial power production respectively.

The Fresnel lens used for the focusing optic 4 and the refracting optics 16 are available from Edmunds Optics or Opto Sigma, or Newport Optical. The semiconductor optical gate wedges 14, as described in the hereinabove referenced U.S. Patents are available through TWO-SIX and Janos Optical.

A conventional solar tracker (not shown) may be utilized in order to cause the focusing optic 4a, 4b to be normal to incoming solar radiation within 0.1 degree.

Importantly, the arrangement of the present invention enables a linear array of photovoltaic cells which can comprise a single junction, either III-V or Si photovoltaic cells. Any number of suitable photovoltaic cells 22-30 may be utilized in the array, while five are shown, any number, for example three, may be utilized depending upon the size of the solar energy production system 2. These “unstacked” solar cell arrays 18 have much lower processing costs using plentiful and less expensive materials. The photovoltaic cell array 18 may have an efficiency exceeding 40% since each photovoltaic material and cell is optimized for its appropriate photon wavelength or energy incident due to the wedges. In turn, the wedges 14 have refractive indices that are approximately the same as the surface of photovoltaic cell array 18 which are connected in series to increase voltage. In addition, these PV cells are preferably impedance matched with one another by external electrical connections in order to maximize the total electrical output.

With an array of five cells, a first cell 22 may be constructed for absorbing solar photons of energy between 0.95 and 1.15 eV, the second cell 24 may be constructed for absorbing photons of energy between 1.20 and 1.4 eV, the third cell 26 may be constructed for absorbing solar photons of energy between 1.45 and 1.7 eV, a fourth cell 28 may be constructed for absorbing solar photons of energy between 1.75 and 2.1 eV, and the fifth cell 30 may be constructed for absorbing solar photons of energy between 2.15 and 2.18 eV.

More specifically, the cell 22 may be GaInAsP, the second cell 24 may be Si, the third cell 26 may be GaAs, the fourth cell 28 may be GaInP₂, and the fifth cell 30 may be Al₂GaInP₄. These cells are based on well established light emitting diode, or LED, industry technology. These LEDs convert electrical current into light of a plurality of wavelengths, each near the band gap of the material. These same LEDS can (with small design modifications) receive sunlight within each wavelength band dispersed by the wedge and convert it into electrical current with high efficiency.

Such LED based photovoltaic cells are available from a number of manufacturers such as, for example, Cree, Inc. However, suitable materials are not limited to those hereinabove recited, but may include materials from class IV, III-V, or II-VI material types which are utilized to optimize the photovoltaic conversion of the near infrared invisible regions of the solar spectrum to electricity. Further description of materials suitable for use in the present invention is described in U.S. Pat. Nos. 5,617,206, 7,238,954, and 7,286,582 to Fay. These references are also incorporated herewith by this specific reference thereto.

As hereinabove noted, the efficiency of the photovoltaic cells 22-30 is provided by the optical gate wedge 18 which causes dispersion sufficient to overcome the limitation imposed by the optics of the angular diameter of the sun (9.3 milli-radians). The refracting optic 16 completes the dispersion and focusing of the light from different wavelengths (photon energy) to the different cells 22-30. The refracting optic 16 further spatially disperses the light perpendicularly to the cells 22-30, in order to prevent overheating of the photovoltaic array 18 cells 22-30.

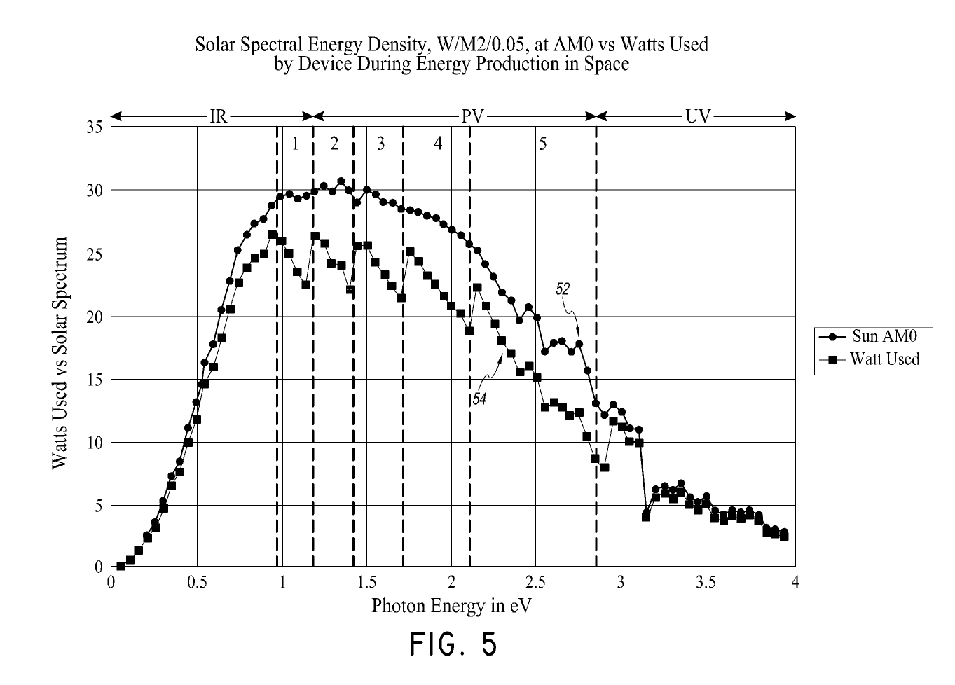

The efficiency of the device is illustrated in FIG. 5. The solar spectrum above the atmosphere (described in the FIG. 5 caption as AM0, or at air mass zero) is illustrated as curve 52 and the watts of electricity produced illustrated as curve 54 across the solar spectrum with the range of solar conversion of each cell indicated by the panels 1, 2, 3, 4, 5 corresponding to the cells 22, 24, 26, 28, 30.

Although there has been hereinabove described a specific solar energy production system and method in accordance with the present invention for the purpose of illustrating the manner in which the invention may be used to advantage, it should be appreciated that the invention is not limited thereto. That is, the present invention may suitably comprise, consist of, or consist essentially of the recited elements. Further, the invention illustratively disclosed herein suitably may be practiced in the absence of any element which is not specifically disclosed herein. Accordingly, any and all modifications, variations or equivalent arrangements which may occur to those skilled in the art, should be considered to be within the scope of the present invention as defined in the appended claims.

What is claimed is:

1. A device for generating solar photovoltaic energy, said device comprising:
an optic for focusing solar radiation;
a collimating optic;
a semi-conductor optical gate wedge disposed proximate a focal point of said collimating optic for dispersing incident solar radiation into a plurality of adjacent wavelength bands;
an array of photovoltaic cells, each cell being formed from a material for absorbing and converting a corresponding wavelength band dispersed by the wedge into electrical energy; and
a refracting optic disposed between the wedge and said array for directing separated wavelength bands onto corresponding photovoltaic cells.

2. The device to claim 1 wherein each cell comprises a single junction, either III-V or Si, photovoltaic cell.

3. The device according to claim 2 wherein the array comprises 3 photovoltaic cells.

4. The device according to claim 2 wherein the array comprises 5 photovoltaic cells.

5. The device according to claim 1 wherein the array comprises five cells, a first cell absorbing solar photons of energy between 0.95 and 1.15 eV, a second cell absorbing solar photons of energy between 1.2 and 1.4 eV, a third cell absorbing solar photons of energy between 1.45 and 1.7 eV, a fourth cell absorbing solar photons of energy between 1.75 and 2.1 eV, and a fifth cell absorbing solar photons of energy between 2.15 and 2.8 eV.

6. The device according to claim 3 wherein the first cell is GaInAsP, the second cell is Si, the third cell is GaAs, the fourth cell is GaInP₂ and the fifth cell is Al₂GaInP₄.

7. The device according to claim 1 wherein the refracting optic is disposed for spatially dispersing light from the wedge onto the photovoltaic cells incident perpendicular to cell surfaces.

8. The device according to claim 1 wherein the wedge includes anti-reflecting coatings to reduce reflection losses.

9. The device according to claim 1 wherein said focusing optics comprises a plurality of Fresnel mirrors.

10. The device according to claim 9 wherein said focusing optic comprises four Fresnel mirrors.

11. The device according to claim 9 wherein said focusing optic comprises 36 Fresnel mirrors arranged in three concentric circles.

12. A method for optimization of a photovoltaic cell array, said method comprising:
focusing solar radiation onto a semi-conductor optical gate wedge;
dispersing the solar radiation by way of the gate wedge into a plurality of adjacent wavelength bands; and
directing the adjacent wavelength bands onto a photovoltaic cell array at generally right angles to the photovoltaic cell array such that the band gap energy of each array element matches the incident photon energy.

13. The method according to claim 12 further comprising arranging a plurality of single junction , either III-V or Si, photovoltaic cells to form the photovoltaic cell array.

14. The method according to claim 13 wherein arranging a plurality of cells comprising arranging three adjacent cells.

15. The method according to claim 13 wherein arranging a plurality of cells comprises arranging five adjacent cells.

16. The method according to claim 12 wherein focusing optic comprises a plurality of Fresnel mirrors.

17. The method according to claim 16 wherein using a plurality of Fresnel mirrors comprises using four Fresnel mirrors.

18. The method according to claim 16 wherein using a plurality of Fresnel mirrors comprises using thirty-six Fresnel mirrors.
